(19) United States
(12) Patent Application Publication
(10) Pub. No.: US 2026/0218816 A1
(43) Pub. Date: Jul. 30, 2026

(54) CABLE FIXING DEVICE, AND CONTROL DEVICE FOR A CONVEYOR DEVICE COMPRISING SUCH A CABLE FIXING DEVICE

(71) Applicant: TGW Logistics GmbH, Marchtrenk (AT)

(72) Inventors: Stefan LINDORFER, Arnreit (AT); Simon KALTSEIS, Haibach ob der Donau (AT); Bernhard Thomas OEGGER, Weibern (AT); Alexander GREINEGGER, Marchtrenk (AT); Stefan PÜHRINGER, Linz (AT); Erwin DÖBERL, Leonding (AT)

(73) Assignee: TGW Logistics GmbH, Marchtrenk (AT)

(21) Appl. No.: 19/147,169

(22) PCT Filed: Jan. 11, 2024
(86) PCT No.: PCT/AT2024/060004

§ 371 Date: Jul. 10, 2025

(30) Foreign Application Priority Data
Jan. 11, 2023 (AT) A50011/2023

(51) Int. Cl. F16L 3/24; F16L 3/04; H02G 3/32; H05K 7/14

(52) U.S. Cl. CPC F16L 3/24; F16L 3/04; H02G 3/32; H05K 7/1491

(57) ABSTRACT

The disclosure relates to a cable fixing device for fixing a cable, comprising a cable clip insertable into a receiving shaft in an insertion direction, with a main body and a spring arm mounted on the main body, wherein the spring arm can be moved toward the main body opposite an action of a spring force and has a spring-loaded first latching element, which cooperates with a second latching element of the receiving shaft in order to fix the cable clip in the receiving shaft. Laterally at the main body, a press-down mechanism is arranged, with which the cable can be pressed, for example against a cable support, and thus fixed. Furthermore, the disclosure relates to a control device which can be connected to cables for controlling drive elements of a conveying device, in particular with a cable fixing device.

### BACKGROUND

The disclosure relates to a cable fixing device for fixing, in particular releasably, a cable, comprising a cable clip insertable into a receiving shaft in an insertion direction. The cable clip has a main body, a press-down mechanism arranged at the main body for fixing the cable, in particular for pressing the cable against a cable support, and a spring arm, which is mounted on the main body and can be moved toward the main body opposite an action of a spring force. The spring arm further has a spring-loaded first latching element, which is arranged at a side of the spring arm facing away from the main body.

Furthermore, the disclosure relates to a control device for controlling at least one drive element of a conveying device for a picking system comprising a housing, which has a housing main body and an interior space. The housing main body comprises a rear wall limiting the interior space. Further, the rear wall has an inner side directed toward the interior space and an outer side facing away from the interior space. The interior space comprises a connection area and a control electronics area adjoining the connection area. What is more, the control device comprises a control electronics unit, which is arranged in the control electronics area, and a connection arrangement, using which the control electronics unit can be connected to at least one cable.

Finally, the disclosure relates to a conveying device and a picking system with such a control device, and to a use of such a control device.

Known from the prior art are cable fixing devices with which a cable can be fixed between a press-down mechanism of a cable clip and a cable support. Usually, the press-down mechanism is arranged centrally on, or formed by, a main body of the cable clip, so that the cable is encompassed and held in position by the main body. It is disadvantageous here that the cable fixing device must be released fully in order to remove the cable. A mere loosening of the cable fixing device is not sufficient to do so. Such a cable fixing device is known, for example, from EP 3 093 541 B1.

To avoid that the cable clip gets lost, it is often provided that the cable clip is formed as one piece with the cable support and/or connected to the cable support in an articulated manner. Such cable fixing devices are known, for example, from U.S. Pat. No. 7,619,164 B2 and EP 2 492 563 B1.

Further known from the prior art are control devices for controlling drive elements of a conveying device, which are mounted laterally on the conveying device. Conventional control devices are often formed with a high overall height in a depth direction in order to improve handling when connecting cables. This requires particularly large amounts of space in a width direction in the assembled state.

### Overview

It is an object of the disclosure to provide an improved cable fixing device. In particular, a simple handling of the cable fixing device is to be achieved.

It is another object of the disclosure to provide an improved control device. In particular, an accessibility of connections for cables is to be improved and/or a need for space is to be minimized.

Further, it is an object of the disclosure to specify an improved conveying device, an improved picking system, and a use for such a control device.

The first object is achieved by a cable fixing device of the kind mentioned in the beginning, wherein the press-down mechanism is arranged, in particular formed, laterally at the main body and has a, in particular exposed, first side and a second side located opposite the first side, wherein the main body and the spring arm are arranged, preferably completely, on the second side of the press-down mechanism.

An advantage achieved with the disclosure is in particular that the main body is arranged on only one side of the cable to be fixed and thus the cable to be fixed is not encompassed by the cable fixing device. On the one hand, this enables the cable fixing device to be realized with a particularly low need for space, in particular with a small width. On the other hand, a lateral removal of the cable is enabled, so that the cable clip need not be extracted from the receiving shaft completely but only loosened. This improves also a handling of the cable fixing operation and reduces the risk of losing the cable clip. The cable clip can in particular be handled one-handedly.

It is expedient if the main body has a first lateral surface, at which the press-down mechanism is arranged. Furthermore, the main body can have a second lateral surface different from the first lateral surface, at which the spring arm is arranged. Particularly preferably, the first and second lateral surfaces are arranged parallel to one another, in particular on opposite sides of the main body, or so as to enclose a right angle.

The cable clip extends in a longitudinal direction between an insertion end and a handling end, wherein the cable clip is inserted into the receiving shaft with the insertion end (first). The handling end preferably remains outside the receiving shaft, so that the cable clip can be removed from the receiving shaft again.

To improve a handling of the cable clip, it can be provided that a handling element, in particular a corrugated surface, is provided at the spring arm and/or at the main body. The handling element is preferably arranged at the handling end.

Furthermore, is preferably provided that the cable clip is manufactured as one piece, in particular using the injection molding method.

The first latching element can cooperate with a second latching element of the receiving shaft in order to fix the cable clip in a fixing position in the receiving shaft. In the fixing position, the cable clip is positioned such in the receiving shaft that the cable is clamped between the press-down mechanism and a cable support.

Advantageously, the cable fixing device comprises a cable support, which is arranged next to the receiving shaft, for example, in particular adjoining the receiving shaft, so that the cable can be fixed by being clamped between the press-down mechanism and the cable support. The cable support can be formed as one piece with the receiving shaft, for example. To this end, the cable support can be arranged, in particular formed, at an outer side of a shaft wall of the receiving shaft, for example.

It is advantageous if the first latching element can be moved from a latched position, in which the first latching element of the receiving shaft cooperates with the second latching element of the receiving shaft, to an unlatched position, in which the first latching element can be moved past the second latching element opposite the insertion direction, by moving the spring arm toward the main body, in particular opposite the action of the spring force. In the unlatched position, the first latching element and the second latching element are no longer cooperating. The cable clip can thus be extracted from the receiving shaft.

It is favorable if the main body and the spring arm are arranged at a mutual distance, wherein the distance can be changed opposite the action of the spring force and the first latching element is in the latched position when the distance corresponds to a first distance and the first latching element is in the unlatched position when the distance corresponds to a second distance, wherein the first distance is greater than the second distance.

Particularly preferably, it is provided that the main body and the spring arm enclose an opening angle, which can be changed opposite the action of the spring force, wherein the first latching element is in the latched position when the opening angle corresponds to a first opening angle, and wherein the first latching element is in the unlatched position when the opening angle corresponds to a second opening angle, wherein the first opening angle is greater than the second opening angle.

To avoid an inadvertent extracting the cable clip from the receiving shaft, it is preferably provided that the cable clip has a loss protection, which comprises a catch element which cooperates with a stop element of the receiving shaft in order to limit an adjustment range of the cable clip opposite the insertion direction, in particular inside the receiving shaft. To this end, it can be provided that the receiving shaft comprises a stop element. The stop element may be provisioned by the second latching element, for example.

Preferably, the catch element is arranged such that the adjustment range is greater than a cable diameter, in particular greater than a maximum cable diameter of a cable to be fixed. To this end, the cable clip can be arranged spaced apart from the press-down mechanism, in particular from the adjustment surface of the press-down mechanism, in a longitudinal direction of the cable clip. It is advantageous if a distance between the catch element and the press-down mechanism, in particular the adjustment surface, corresponds to at least 40%, in particular 50% to 75%, of a total length of the main body of the cable clip. Particularly preferably, the distance between the press-down mechanism and the catch element is greater than the cable diameter, preferably at least 0.5 cm, particularly preferably at least 1 cm.

It is expedient if the latching element and the catch element are positioned so as to be spaced apart from each other in a longitudinal direction of the cable clip. Preferably, in a longitudinal direction of the cable clip, a distance between the insertion end and the catch element is smaller than a distance between the insertion end and the latching element.

It is favorable if the catch element is arranged at the main body and/or at the spring arm, in particular at the side of the spring arm facing away from the main body. Preferably, the catch element is configured as a, in particular semicircular, projection arranged at the main body and/or at the spring arm.

Preferably, the catch element can be moved from a securing position, in which the catch element cooperates with the stop element, to a releasing position, in which the catch element can be moved past the stop element opposite the insertion direction. It is thereby achieved, on the one hand, that the catch element in the securing position engages behind the stop element, in particular behind the second latching element, of the receiving shaft, whereby an extraction movement opposite the insertion direction is limited by the projection. An inadvertent extracting the cable clip from the receiving shaft can thus be prevented. On the other hand, in the releasing position, the catch element does not engage behind the stop element, in particular behind the second latching element, so that the cable clip can be extracted from the receiving shaft completely.

If the catch element is arranged at the main body and/or at the spring arm, the catch element can be moved from the securing position to the releasing position by a relative movement between the main body and the spring arm, in particular by a movement of the spring arm toward the main body.

Advantageously, it is provided that the catch element is in a first securing position when the opening angle corresponds to the first opening angle, is in a second securing position when the opening angle corresponds to the second opening angle, and is preferably in a releasing position when the opening angle corresponds to a third opening angle, which is smaller than the second opening angle.

It is favorable if the cable fixing device further comprises the receiving shaft, into which the cable clip can be inserted. The receiving shaft has preferably an insertion opening and a second latching element, preferably a latch, in particular arranged at an interior wall of the receiving shaft, wherein the first latching element and the second latching element cooperate in order to limit an extraction movement opposite the insertion direction when the cable clip is in a fixing position in the receiving shaft.

The receiving shaft is preferably dimensioned and/or configured such in a longitudinal direction that the first latching element can be accommodated completely in the receiving shaft, in particular such that the first latching element engages behind the second latching element. To this end, a total length of the receiving shaft can be greater than a longitudinal distance between the insertion end of the first latching element and an end of the first latching element facing away from the insertion end in a longitudinal direction of the cable clip. Alternatively or additionally, the receiving shaft can be configured open on both ends.

It is advantageous if the first latching element is pretensioned by the spring force toward the interior wall of the receiving shaft when the cable clip is inserted into the receiving shaft. The spring force is preferably exerted by the spring arm or a spring element operatively connected to the spring arm.

The receiving shaft comprises preferably four circumferentially arranged shaft walls, which limit a shaft interior space and provision the interior wall. The second latching element is preferably formed at one of the shaft walls so as to protrude into the shaft interior space.

It is favorable if the first latching element has multiple latches, which are arranged in succession in a longitudinal direction of the spring arm. This enables the cable clip to be fixed in the receiving shaft in different insertion depths and thus the cable fixing device to be adapted to different cable diameters. Particularly preferably, the latches each extend orthogonally to the longitudinal direction of the spring arm.

Here, the different insertion depths each correspond to a fixing position for a cable of a specific cable diameter. For example, the first latching element may have three latches, wherein in a first insertion depth only a first latch of the latches engages behind the second latching element in order to fix the cable clip in a first fixing position. In a second insertion depth, a second latch of the latches can engage behind the second latching element in order to fix the cable clip in a second fixing position. Further, in a third insertion depth, a third latch of the latches can engage with the second latching element in order to fix the cable clip in a third fixing position.

Advantageously, the press-down mechanism is configured for pressing down a cable to be fixed in an insertion direction, in particular against the cable support. To this end, the press-down mechanism preferably has an adjustment surface which can be adjusted to the cable to be fixed.

It is favorable if the press-down mechanism is configured resilient, in particular elastically deformable.

Furthermore, it can be provided that friction-enhancing means, preferably an anti-slip coating and/or multiple, in particular tooth-like, projections, are arranged at the press-down mechanism, for example at a contact surface of the press-down mechanism, which contact surface can be adjusted to the cable. This improves a fixing of the cable, in particular in a longitudinal direction of the cable.

Further, it is favorable if a first guiding element is arranged at the main body, which first guiding element cooperates with a second guiding element arranged at the interior wall of the receiving shaft in order to guide the main body in an insertion direction. The first guiding element can be configured, for example, as a projection extending along a longitudinal direction of the main body, in particular formed at the main body. Analogously, the second guiding element can be configured as a projection extending along a longitudinal direction of the receiving shaft, in particular arranged, preferably formed, at the interior wall of the receiving shaft.

Preferably, it is provided that the cable fixing device, as described above, comprises a cable support for receiving a cable to be fixed. Furthermore, the cable fixing device can comprise an electrically conductive inlay element, which is positioned on the cable support. Particularly preferably, the electrically conductive inlay element can be grounded, for example by being electrically connected to a rear wall and/or a metal plate of a control device described below. This enables a requirement of an additional shield support to be avoided and further the handling of the cable fixing device to be simplified. To this end, the inlay element can be attached to the cable support for example using an electrically conductive fastening element, for example an electrically conductive rivet, screw, adhesive or suchlike, wherein the fastening element is grounded or can be grounded.

The other object is achieved, making use of the advantages and effects described above, by a control device of the kind mentioned in the beginning, wherein the control device comprises a cable fixing device, which is arranged in the connection area and configured according to any one of the aspects described above.

An advantage achieved with the disclosure is in particular that cables which are connected to the control electronics unit of the control device can be fixed in the connection area in a simple and particularly space-saving manner. Here, a cable can be placed laterally into a cable guide or cable support and fixed by pressing the cable clip in an insertion direction. The cable clip described can be handled one-handedly here. The cable fixing device has a particularly low need for space in a width direction, so that multiple cables can be guided to the control electronics unit next to one another in a particularly space-saving manner.

Furthermore, the cable is relieved of tension by the cable fixing device, so that the cable can be guided essentially laterally out of the interior space of the control device. This enables the control device to be realized with a low overall height.

An overall height of the control device is understood to mean a distance between the rear wall and a highest point of the control device in a depth direction. The depth direction is aligned orthogonal to the rear wall.

The receiving shaft and/or the cable support described above can be arranged in the connection area so as to protrude downward from the rear wall in a depth direction. Particularly preferably, the receiving shaft and/or the cable support are configured as one piece with the main body.

The other object is further achieved by a control device of the kind mentioned in the beginning, in which the housing main body comprises a connection wall protruding downward from the rear wall in a depth direction and limiting the connection area and the connection wall has multiple lead-through openings for cables and forms multiple guiding surfaces at an outer side facing away from the connection area for guiding cables, wherein the guiding surfaces each adjoin an a lead-through opening and are configured convex, preferably sigmoid, at least in sections.

An advantage achieved with the disclosure is in particular that the cables can be guided laterally out of the control device and toward a rear plane located in the rear wall via the convex section of the guiding surfaces. If the control device is mounted with the rear wall at a frame profile of a conveying device, for example, the cables can be guided to the frame profile via the guiding surfaces, so that the control device can be realized with a low overall height and can thus be arranged particularly flat at the frame profile.

Advantageously, the guiding surface comprises a convex section adjoining the lead-through opening. The cable can thus be guided along the convex section toward the rear wall.

Furthermore, the guiding surface can comprise a concave section adjoining the convex section, so that the guiding surface is essentially sigmoid-shaped. Along the concave section, the cable is curved in the other direction, so that the cable can be guided away from the control device essentially parallel to the frame profile and parallel to the rear wall, respectively.

Furthermore, the other object is achieved with a control device of the kind mentioned in the beginning, wherein the control electronics unit comprises a first printed circuit board and a second printed circuit board, on each of which a control circuit is arranged and which are arranged (stacked) above one another in the control electronics area of the housing, and the connection arrangement comprises a first connection unit, which can be connected to at least one first cable, arranged on the first printed circuit board and facing the connection area and a second connection unit, which can be connected to at least one second cable, arranged on the second printed circuit board and facing the connection area, wherein the second printed circuit board is configured smaller than the first printed circuit board in at least one extension direction and arranged such in the housing that the first connection unit and the second connection unit are arranged mutually offset in a connection direction.

An advantage thereby achieved is in particular that the cables can be connected to the control electronics unit essentially laterally, whereby also a particularly low overall height of the control device can be realized.

The offset configuration of the connection units further enables an improved accessibility of the connection units, so that the cables can be connected in a simple manner when mounting the control device.

It is favorable if the first connection unit and the second connection unit are each arranged at an edge of the respective printed circuit board facing the connection area. The connection direction runs preferably orthogonally to this edge toward an opposite edge. At the opposite edge of the respective printed circuit board, another first and second connection unit of the connection arrangement can be provided in the same manner.

Advantageously, the first and second printed circuit boards are arranged in the control electronics area parallel to the rear wall. Furthermore, it is favorable if the second printed circuit board is arranged at a side of the first printed circuit board facing away from the rear wall.

Particularly preferably, it is provided that the printed circuit boards are stacked in a depth direction aligned orthogonal to the rear wall.

It is advantageous if the first connection unit and/or second connection unit each have at least one connection, preferably multiple connections, which is/are preferably configured as a plug or as a socket, for example for power cables or data cables. Particularly preferably, the connection units comprise a CAN bus, Profinet, Ethernet and/or power connection, for example.

If the control device is mounted on a conveying device, it may be that both accessibility and illumination for the first connection unit, which is arranged at the first printed circuit board, are better than for the second connection unit, which is arranged at the second printed circuit board. It is therefore preferably provided that the first connection unit comprises connections that are small and/or difficult to handle and the second connection unit comprises connections that are large and/or easy to handle.

Further, it is favorable if the first connection unit and/or the second connection unit protrude into the connection area.

Furthermore, the connection arrangement is preferably arranged such that the connection direction, in which, for example, a cable and a connection can be connected, is aligned parallel to the first printed circuit board and/or to the second printed circuit board.

To achieve a particularly compact design, in particular a particularly low overall height, it is preferably provided that the first printed circuit board and the second printed circuit board are aligned parallel to one another and preferably parallel to the rear wall of the housing.

As described above, it can be provided that the connection wall forms multiple guiding surfaces for guiding cables at its outer side. Here, it is favorable if some of the guiding surfaces form a first group and some of the guiding surfaces form a second group, wherein the guiding surfaces of the first group adjoin the respective lead-through opening at a first orthogonal distance to the rear wall and the guiding surfaces of the second group adjoin the respective lead-through opening at a second orthogonal distance to the rear wall. This enables cables which are intended for the first printed circuit board and cables which are intended for the second printed circuit board to be guided into the connection area at the corresponding height. Here, it is in particular provided that the second orthogonal distance is greater than the first orthogonal distance.

Particularly preferably, the guiding surfaces of the first group are assigned to the first connection unit and the guiding surfaces of the second group are assigned to the second connection unit.

To seal the housing, in particular the connection area, for example against splashing water and/or dust, it is preferably provided that the housing has at least one elastic sealing element, which is arranged in the lead-through openings.

Preferably, the lead-through openings are configured as slots which are open against an edge of the connection wall, in particular against an upper edge of the connection wall facing away from the rear wall, so that cables can be inserted into the respective slot through the open side. The sealing element can also have open slots which are open against an edge and into which cables can be inserted. Here, it is preferably provided that the sealing element is formed like a comb and inserted into the slots at the open edge of the connection wall.

Alternatively or additionally, the connection wall can be configured double-walled with an intermediate space. The sealing element can be arranged, in particular at least partially, in the intermediate space. Here, it is preferably provided that slots of the sealing element and the lead-through openings are aligned with one another. Alternatively, multiple sealing elements can be provided, each of which is arranged in a lead-through opening.

Advantageously, it is provided that multiple guiding elements, preferably guiding brackets, in particular adapted to a cable diameter, are arranged at the outer side of the connection wall in order to guide, in particular fix, a cable along the guiding surfaces. The guiding elements are arranged such that the cables can be received between the guiding elements and the guiding surfaces, for example.

To protect the printed circuit boards against contamination and suchlike, it is preferably provided that the housing has a cover, with which the control electronics area is covered.

Furthermore, the housing, in particular the housing main body, preferably has a separating wall protruding downward from the rear wall in a depth direction, which separating wall separates the connection area from the control electronics area, wherein the separating wall has multiple connection openings for the connection arrangement, which connect the connection area to the control electronics area.

It is favorable if cables can be guided through the connection openings to connection units, in particular to connections, of the connection arrangement, or the connection units, in particular the connections, of the connection arrangement are aligned with the connection openings, arranged in the connection openings and/or guided through the connection openings.

Furthermore, it is advantageous if the separating wall has a first separating wall section protruding downward from the rear wall in a depth direction, in which first separating wall section at least one first connection opening of the connection openings is arranged, a second separating wall section arranged offset from the first separating wall section in a connection direction and extending in a depth direction, in which second separating wall section at least one second connection opening of the connection openings is arranged, and a third separating wall section connecting the first separating wall section and the second separating wall section. The separating wall is thus configured essentially stepped and adapted to different dimensions of the printed circuit boards and/or adapted to the offset positioning of the connection units.

It is expedient if the first connection unit is aligned with, arranged in and/or guided through the first connection opening. Optionally, the first connection unit protrudes into the connection area. Further, it is favorable if the second connection unit is aligned with, arranged in and/or guided through the second connection opening. A connection between the cable and the control electronics unit can thus be made through the respective connection opening. Optionally, the first and/or second connection unit protrudes into the connection area.

To design the connection area such that it is accessible for connecting cables, it is preferably provided that the housing has a closing flap which is mounted on the housing main body so as to be movable, in particular pivotable, between an opened position, in which the connection area is accessible, and a closed position, in which the connection area is closed. A pivot axis, about which the closing flap can be pivoted, is aligned preferably parallel to the rear wall. It is favorable if the closing flap has a retaining mechanism, using which the closing flap can be fixed in the opened position.

Advantageously, it is provided that the closing flap is pivotably mounted on the housing main body using a hinge, wherein the hinge has a hinge pin mounted on the closing flap and a pin receptacle arranged in the housing, wherein the hinge pin can be extracted from the pin receptacle in a radial direction, so that the closing flap can be removed from the housing main body.

The pin receptacle can be configured C-shaped and interrupted along a circumferential surface toward the connection area in order to form an opening. The housing, in particular the housing main body, can further have an insert channel extending from the opening of the pin receptacle to the connection area in a radial direction, using which the hinge pin can be inserted into the pin receptacle in a radial direction. Preferably, a width of the opening and an opening of the pin receptacle are (slightly) smaller than a pin diameter, so that the pin can be inserted into the pin receptacle while elastically deforming the housing, in particular side walls of the insert channel.

To attach the control device to the frame profile of the conveying device, it is preferably provided that the housing has a first hook-in strap arranged at the outer side of the rear wall and facing a first longitudinal side of the control device and a second hook-in strap arranged at the outer side of the rear wall and facing a second longitudinal side of the control device. The control device can thus be hooked in at the frame profile in a simple manner. In particular, mounting sections of the support rail of the conveying device, which are spaced apart in alignment with one another and aligned parallel to one another, can be received between the hook-in straps and the rear wall in order to hook the control device into the support rail. The mere hooking-in of the control device allows for the control device to be slidably attached to the frame profile and thus positioned, for example in a longitudinal direction of the frame profile. Particularly preferably, multiple first hook-in straps spaced apart in a longitudinal direction of the control device and multiple second hook-in straps spaced apart in a longitudinal direction of the control device are provided.

In the interior space of the housing, hollows aligned with the hook-in straps, in particular adapted in shape and size to the hook-in straps, can be provided. This enables the hook-in straps to be bent into the interior space, so that interfering contours caused by the hook-in straps at the outer side of the rear wall can be avoided and a wall mounting is enabled.

To fix the control device also against sliding along the frame profile, it is preferably provided that the housing has a fixing device for (releasably) attaching the control device to a frame profile of the conveying device, wherein the fixing device has a bolt passing through the rear wall with a screw head arranged at the inner side of the rear wall and a rotary bar which is fixedly connected to the bolt and arranged at the outer side of the rear wall. The rotary bar is preferably arranged such that one of the mounting sections, in particular an upper mounting section, of the frame profile can be fixed between the rotary bar and the rear wall.

The fixing device, in particular the rotary bar and/or the bolt, can be arranged at the housing so as to be removable. This enables interfering contours caused by the fixing device at the outer side of the rear wall to be avoided and a wall mounting to be enabled.

It is favorable if the screw head is configured as a hexagon screw head and/or as a hexagon socket screw head. Furthermore, it can be provided that the screw head is further configured as a cross screw head and/or slotted screw head. Particularly preferably, the screw head is configured as a combination screw head combining a hexagon, hexagon socket and cross screw head.

Further, it is advantageous if the control electronics unit comprises a module, in particular a processor module, and the rear wall has a recess, in particular passing through the rear wall, which is adapted in shape and size to the module, wherein the module is at least partially received in the recess.

Here, the module, in particular the processor module, can comprise a third printed circuit board, which is in particular arranged parallel to the first printed circuit board and/or parallel to the rear wall, in particular between the first printed circuit board and the rear wall.

To distribute a heat generated by the control electronics unit and/or by the module, in particular the processor module, over an enlarged surface and/or to guide the heat away from the control electronics unit, for example to the frame profile of the conveying device, it is preferably provided that the housing has a metal plate, which is arranged at the outer side of the rear wall. The control device is preferably mountable on the frame profile or may be mounted on the frame profile such that the metal plate contacts the frame profile, in particular the mounting sections of the frame profile, in order to dissipate heat to the mounting sections of the frame profile.

Preferably, the control device comprises a heat conduction pad, which is arranged in the recess and which thermally connects the metal plate and the module, in particular the processor module.

It is expedient if the control device comprises a central control electronics area and two connection areas arranged at opposite sides of the control electronics area. To this end, the housing, in particular the housing main body, can be configured symmetrical.

Another object is achieved, making use of the advantages and effects described above, with a conveying device for transporting articles for a picking system, which conveying device comprises frame profiles extending parallel to one another, conveying elements mounted on the frame profiles, at least one drive element for driving one or multiple conveying elements, and a control device for controlling the at least one drive element, wherein the control device is mounted on one of the frame profiles and configured according to any one of the aspects described above.

Here, the frame profiles are preferably configured C-shaped and have a vertically aligned base and two limbs protruding orthogonally downward from the base. A mounting section aligned parallel to the base can be arranged at each of the limbs, into which mounting section the control device can be hooked, for example using the hook-in straps described above. The mounting sections preferably protrude downward from the respective limb and are directed toward each other, for example.

Advantageously, the control device is attached such to the frame profile that the rear wall of the housing is aligned parallel to the base of the frame profile on which the control device is mounted. Here, the optional metal plate is preferably in thermal and/or electrical contact with the frame profile. The frame profile and/or the metal plate may be electrically grounded.

The control device is preferably oriented such that the depth direction of the control device described above extends in a width direction of the conveying device. This enables a particularly narrow design of the conveying device due to the control device according to the disclosure.

Furthermore, the other object is achieved, making use of the advantages and effects described above, with a picking system which comprises an article storage, at least one picking station for picking articles according to orders and a conveying device for transporting articles inside the picking system, wherein the conveying device is configured according to any one of the aspects described above.

The article storage may be a rack storage operated in an automated manner with a plurality of storage racks and storage and retrieval devices. The article storage can be connected to the picking station in terms of conveyance, for example by the conveying device. The storage and retrieval devices can be configured for removing articles from the storage racks and transferring the articles directly or indirectly to the conveying device, for example using a handover device.

The picking station can comprise a picking device operated in an automated manner and/or a manual picking device, for example. At the picking station, articles can be reloaded from source containers, for example storage containers, into target containers, for example shipping containers, according to a picking order.

The picking system can further comprise a master computer, which is connected to the control device by a communication link, for example CAN bus, Profinet, Ethernet or suchlike.

Finally, the other object is achieved, making use of the advantages and effects described above, with the use of a control device described above for controlling drive elements of a conveying device, in particular of a conveying device according to any one of the aspects described above, in a picking system, in particular in a picking system according to any one of the aspects described above.

For the purpose of better understanding of the disclosure, it will be elucidated in more detail by means of the figures below.

### BRIEF DESCRIPTION OF THE FIGURES

These show in a very simplified schematic representation:

FIG. 1 a cable clip of a cable fixing device;

FIG. 2 a receiving shaft for the cable clip in a cross-sectional representation;

FIGS. 3a to 3d the cable fixing device in a cross-sectional representation;

FIGS. 4a and 4b the cable fixing device in a front view;

FIG. 5 the cable fixing device in a perspective view;

FIG. 6 the cable fixing device in another cross-sectional representation;

FIGS. 7a and 7b a control device with opened closing flap;

FIG. 8 a detailed view of a hinge of the closing flap;

FIGS. 9a and 9b a control electronics unit of the control device;

FIGS. 10a and 10b a connection area of the control device with connected cables;

FIGS. 11a and 11b a control device mounted on a frame profile of a conveying device;

FIGS. 12a and 12b a screw head and bolt of a fixing device of the control device;

FIG. 13 the conveying device with the control device mounted thereon; and

FIG. 14a a picking system.

### DETAILED DESCRIPTION OF THE EMBODIMENTS

First of all, it is to be noted that, in the different embodiments described, equal parts are provided with equal reference numbers and/or equal component designations, where the disclosures contained in the entire description may be analogously transferred to equal parts with equal reference numbers and/or equal component designations. Moreover, the specifications of location, such as at the top, at the bottom, at the side, chosen in the description refer to the directly described and depicted figure, and in case of a change of position, are to be analogously transferred to the new position.

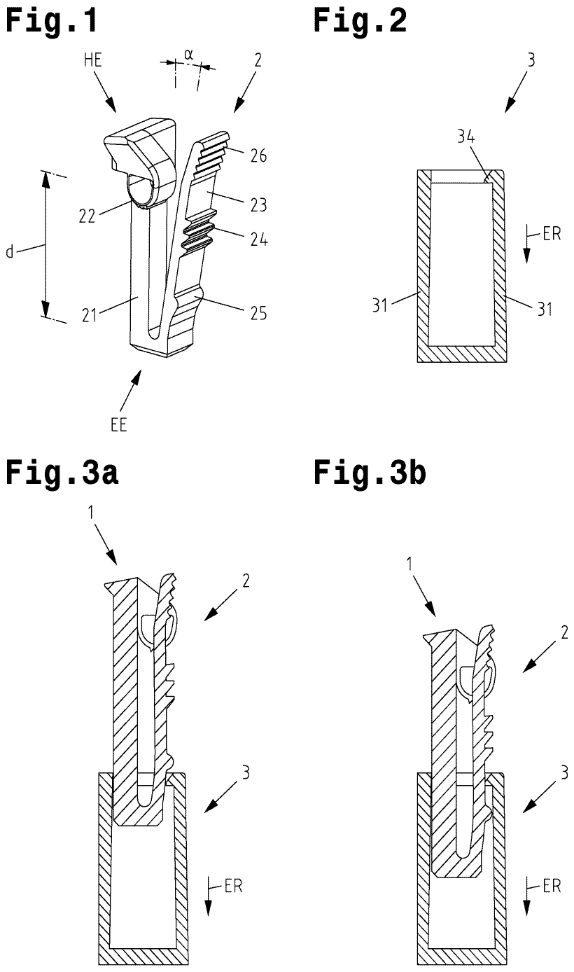

FIG. 1 shows a perspective view of a cable fixing device 1, which comprises a cable clip 2. The cable clip 2 extends in a longitudinal direction from a handling end HE to an insertion end EE and can be inserted into a receiving shaft 3 represented in FIG. 2 in an insertion direction ER essentially with the insertion end EE first. To this end, the cable clip 2 can be handled at the handling end HE, essentially between two fingers.

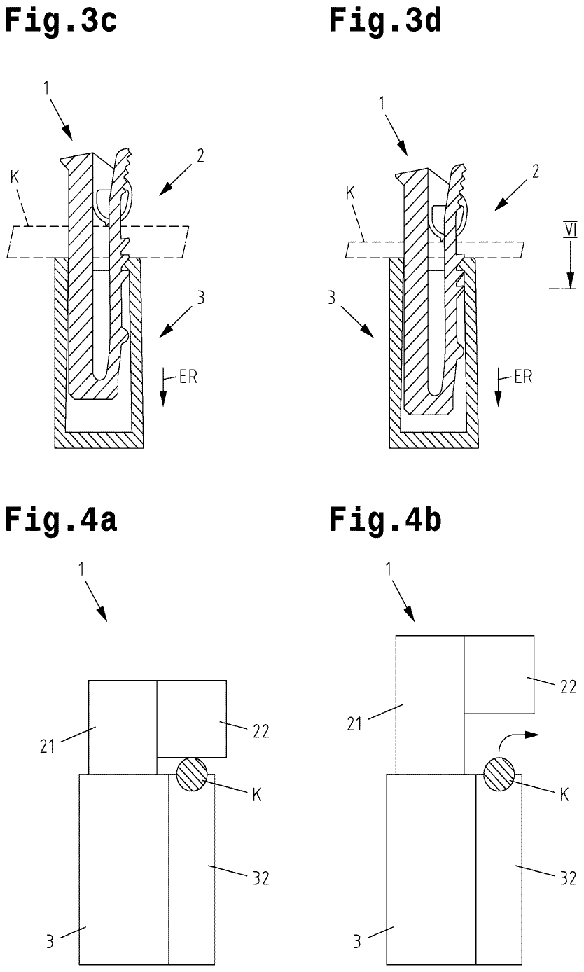

As can be seen in FIG. 1, the cable clip 2 comprises a main body 21 and a press-down mechanism 22 arranged at the main body 21 for pressing down a cable K in an insertion direction ER, as shown in FIG. 3c and FIG. 3d and in FIG. 4a.

Furthermore, the cable clip 2 has a spring arm 23 mounted on the main body 21. The spring arm 23 can be moved toward the main body 21 opposite an action of a spring force in order to tension the main body 21. To this end, the cable clip 2 can be squeezed at the handling end HE, in particular the spring arm 23 can be pressed toward the main body 21. The spring arm 23 and the main body 21 preferably enclose an opening angle α, which can be changed by moving the spring arm 23 toward the main body 21. Preferably, the spring arm 23 and the main body 21 are configured such that the cable clip 2 is configured essentially V-shaped.

To fix the cable clip 2 in the receiving shaft 3, the cable clip 2 comprises a spring-loaded first latching element 24. To this end, the latching element is arranged at the spring arm 23. As can further be seen in FIG. 1, the first latching element 24 can have multiple latches in order to fix the cable clip 2 in the receiving shaft 3 in different insertion depths. FIG. 3c and FIG. 3d show the cable clip 2 arranged and fixed in the receiving shaft 3 in two different insertion depths by way of example.

Furthermore, the cable clip 2 can have an optional loss protection, which comprises a catch element 25. The catch element 25 can be arranged at the main body 21 or, as shown in FIG. 1, at the spring arm 23 spaced apart from the first latching element 24 in a longitudinal direction of the cable clip 2. The catch element 25 can cooperate with a stop element of the receiving shaft 3 in order to avoid an inadvertent extracting the cable clip 2 from the receiving shaft 3.

To improve handling, the cable clip 2 can comprise a handling element 26 arranged at the handling end HE, in particular at the spring arm 23. The handling element 26 can be configured as a corrugated surface of the spring arm 23, for example.

FIG. 2 shows the receiving shaft 3 in a cross-sectional representation. The receiving shaft 3 is configured open at a first end, so that the cable clip 2 can be inserted into the receiving shaft 3 in an insertion direction ER. At a second end opposite the first end in an insertion direction ER, the receiving shaft 3 can also be configured open or, as shown in FIG. 2, closed.

A longitudinal extension of the receiving shaft 3 preferably corresponds to at least one longitudinal distance d between the insertion end EE of the cable clip 2 and an end of the first latching element 24 facing away from the insertion end EE, so that the first latching element 24 can be accommodated completely in the receiving shaft 3.

The receiving shaft 3 comprises a second latching element 34, which is arranged in an interior space of the receiving shaft 3, preferably at an interior wall formed by a shaft wall 31 of the receiving shaft 3. The second latching element 34 can be arranged at the first end of the receiving shaft 3, for example.

The receiving shaft 3 can further comprise the stop element described above, which cooperates with the catch element 25, wherein the stop element is preferably formed by the second latching element 34.

FIG. 3a to FIG. 3d show an inserting of the cable clip 2 into the receiving shaft 3 in a cross-sectional representation.

Here, the cable clip 2 is inserted into the receiving shaft 3 with the insertion end EE and fitted into the receiving shaft 3 by a movement in an insertion direction ER, in particular by pressing the cable clip 2 downward.

As can be seen in FIG. 3b, the catch element 25 is first moved past the second latching element 34. Here, the catch element 25 is in a first or second securing position, in which the catch element 25 engages behind the second latching element 34. To extract the cable clip 2 from the receiving shaft 3, the receiving shaft 3 can be pressed together, in particular the opening angle α can be reduced, such that the catch element 25 is brought to a releasing position, in which the catch element 25 can be moved past the second latching element 34.

To fix a cable K, the cable clip 2 can be arranged in a fixing position in the receiving shaft 3, as shown in FIG. 3c and FIG. 3d. To fix a cable K with a first cable diameter, for example, the cable clip 2 can be arranged in a first fixing position represented in FIG. 3c, in which the cable clip 2 is engaged, with its first latching element 24, in particular with a first latch of the first latching element 24, in the second latching element 34 in a first insertion depth. Further, the cable clip 2 can be arranged in a second fixing position represented in FIG. 3d, in which the cable clip 2 is engaged, with its first latching element 24, in particular with a second latch of the first latching element 24, in the second latching element 34 in a second insertion depth in order to fix a cable K with a second cable diameter. In the example represented, the second cable diameter is smaller than the first cable diameter. The cable K is indicated with dashed lines in FIG. 3c and FIG. 3d.

In FIG. 4a and FIG. 4b, the cable fixing device 1 is represented in a very simplified manner in a front view. The cable fixing device 1 can comprise an optional cable support 32, on which the cable K rests and against which the cable K can be pressed by the press-down mechanism 22 in order to fix the cable K.

In the example represented, the cable clip 2 in FIG. 4a is arranged in a fixing position, in which the cable K is fixed between the press-down mechanism 22 and the cable support 32. This corresponds essentially to the configuration represented in FIG. 3c or FIG. 3d.

In FIG. 4b, the cable clip 2 is arranged in a releasing position, in which the cable K can be removed laterally, as indicated by a curved arrow. This corresponds essentially to the configuration represented in FIG. 3b.

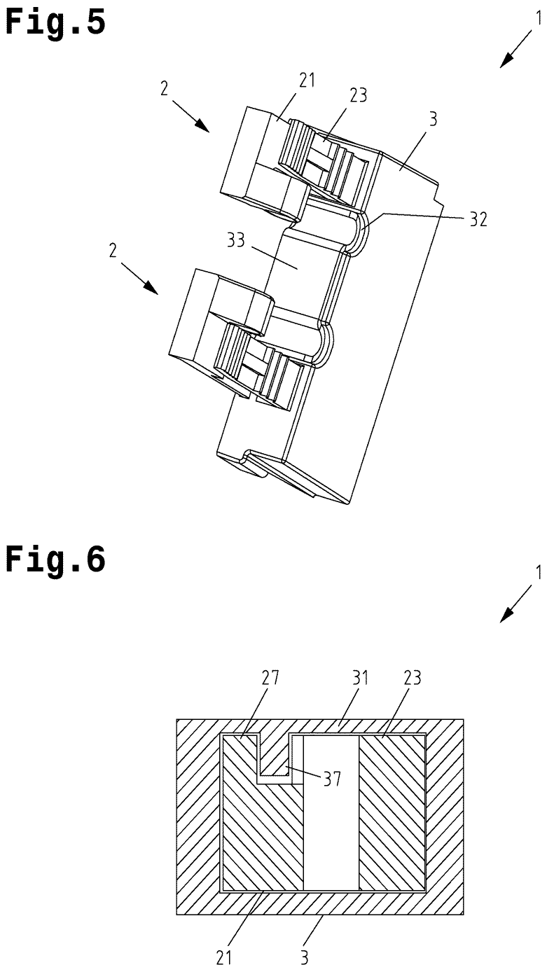

FIG. 5 shows two cable fixing devices 1 arranged next to each other, which are configured essentially identical, in particular mirror-symmetrical, and each comprise a cable clip 2 and a receiving shaft 3. The cable fixing devices 1 comprise an inlay element 33, which is arranged on the cable support 32. The inlay element 33 is preferably made from an electrically conductive material and grounded. To this end, the inlay element can be fixed to the cable support 32, for example using a screw or a rivet. In the example represented, the cable fixing devices arranged next to each other have a joint inlay element 33. Alternatively, it can be provided that there is only one cable fixing device 1 with an inlay element 33. It can also be provided that two cable fixing devices 1 arranged next to each other have an inlay element 33 each.

FIG. 6 shows a cross section through the cable fixing device 1 in a plane VI indicated with a dash-dotted line in FIG. 3d. As can be seen in the cross section, the cable clip 2 can comprise a first guiding element 27, which is arranged at the main body 21, in particular formed at the main body 21. Furthermore, the receiving shaft 3 can comprise a second guiding element 37 cooperating with the first guiding element 27, which second guiding element 37 is arranged, for example formed, at an inner side of the receiving shaft 3, in particular at the shaft wall 31 of the receiving shaft 3. The cooperating guiding elements 27, 37 enable the cable clip 2 to be guided in the receiving shaft 3 in an insertion direction ER.

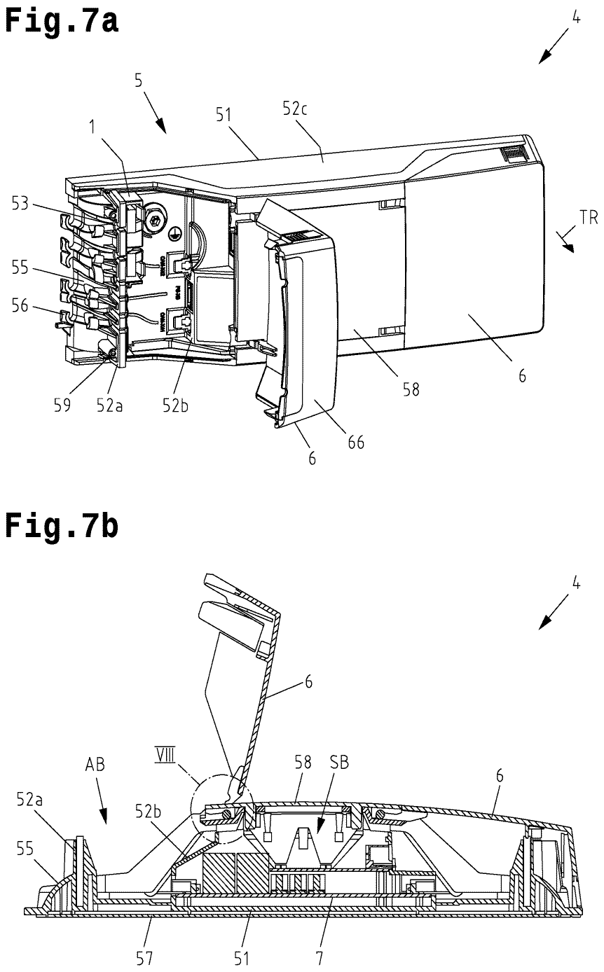

FIG. 7a shows a perspective view of a control device 4 for controlling at least one drive element of a conveying device 9 for a picking system 100. FIG. 7b shows the control device 4 in a cross-sectional representation.

The control device 4 comprises a housing with an interior space, which can be subdivided into a control electronics area SB and a connection area AB. The housing can have a cover 58, with which the control electronics area SB is covered.

Furthermore, the housing has a housing main body 5 with a rear wall 51 limiting the interior space, in particular in a depth direction TR. Here, the depth direction TR is aligned orthogonal to the rear wall 51. The cover 58 for the control electronics area SB is arranged preferably parallel to the rear wall 51 and spaced apart from the rear wall 51 in a depth direction TR.

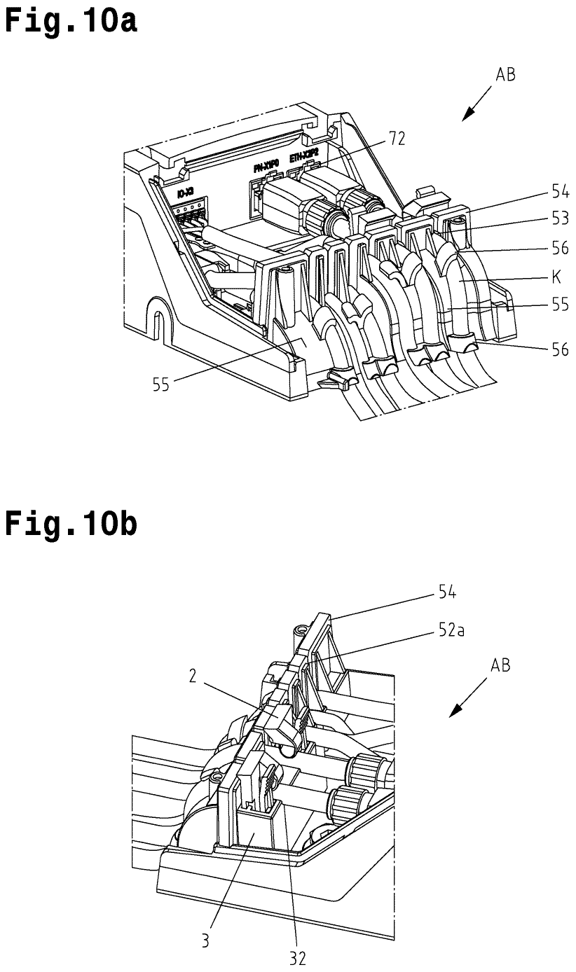

Further, the housing main body 5 can comprise a connection wall 52a protruding downward from the rear wall 51 in a depth direction TR, which connection wall 52a laterally bounds the connection area AB. In the connection wall 52a, preferably multiple lead-through openings 53 are provided, through which cables K can be guided from the exterior into the connection area AB, as shown in FIG. 10a and FIG. 10b.

At an outer side of the connection wall 52a facing away from the connection area AB, the connection wall 52a can form multiple guiding surfaces 55 adjoining the lead-through openings 53. The guiding surfaces 55 are preferably configured convex at least in sections, so that the cables K, as shown in FIG. 10a, can be guided away from the lead-through openings 53 essentially waterfall-like. Further, to guide the cables K away essentially parallel to the rear wall 51, it can be provided that the guiding surfaces 55 have a concave section adjoining a convex section and are thus configured sigmoid.

Furthermore, multiple frame-shaped guiding elements 56 are arranged, preferably at each of the guiding surfaces 55, which frame-shaped guiding elements 56 are formed such that the cables K can be received between the guiding surfaces 55 and the guiding elements 56.

Further, the housing can comprise a separating wall 52b protruding downward from the rear wall 51 in a depth direction TR, which separating wall 52b separates the control electronics area SB and the connection area AB from each other. Here, the separating wall 52b can be made as one piece with the housing main body 5, for example.

Alternatively, the separating wall 52b can be made as one piece with the cover 58 and connected with the cover 58 using a living hinge, for example. The separating wall 52b can comprise latches, for example, which cooperate with latch receptacles in the rear wall 51 in order to connect the separating wall 52b to the rear wall 51.

What is more, it can be provided that the housing main body 5 comprises two side walls 52c extending parallel to one another and aligned orthogonal to the connection wall 52a. It can thus be provided that the rear wall 51, the connection wall 52a and the side walls 52c limit the interior space.

To dissipate a heat from the control device 4, the housing can comprise a metal plate 57, which is arranged at an outer side of the rear wall 51.

Furthermore, it is preferably provided that the control device 4 comprises one or multiple cable fixing devices 1, which are arranged in the connection area AB. These cable fixing devices 1 can be configured as described in relation to FIG. 1 to FIG. 4b. The receiving shaft 3 and/or the cable support 32 can be configured as one piece with the housing main body 5 and/or so as to protrude downward from the rear wall 51 in a depth direction TR.

To cover the connection area AB so as to be openable, the housing preferably comprises a closing flap 6 mounted on the housing main body 5. In the example represented, a first connection area AB represented on the left hand side in FIG. 7a and FIG. 7b is accessible via an opened closing flap 6 on the one hand and a second connection area AB represented on the right hand side in FIG. 7a and FIG. 7b is covered by a closed closing flap 6 on the other hand. The closing flap 6 represented on the left hand side is thus in an opened position and the closing flap 6 represented on the right hand side is in a closed position.

Furthermore, the housing can comprise one or multiple optional screw domes 59 protruding downward from the rear wall, which screw domes 59 are positioned such that the closing flap 6 can be fixed by being screwed down in the closed position. To this end, the closing flap 6 can have corresponding bores or bore markings for applying the bores, each of which is aligned in a line with a screw dome 59 when the closing flap 6 is in the closed position. Thus, a screw can be screwed into the screw dome 59 through the bore in order to fix the closing flap 6 in the closed position. It is thus ensured that the closing flap 6 cannot be opened without tools.

Further, the closing flap 6 comprises preferably a side part 66 and a, in particular U-shaped, recess opened toward a periphery of the closing flap 6, which can be closed by the side part 66, which can be removed and/or clipped on. When the side part 66 is removed, the recess is opened, so that cables K can be guided laterally out of the housing through this recess, for example when the control device 4 is mounted on a wall. The side part 66 can preferably be stored in and/or at the cover after removal. To this end, the cover can comprise a receptacle for the side part 66 at an inner side, so that the side part 66 does not get lost.

As can further be gleaned from FIG. 7a and FIG. 7b, the housing can be configured essentially mirror-symmetrical, wherein the interior space has a centrally arranged control electronics area SB and connection areas AB laterally adjoining the control electronics area SB. The connection areas AB are preferably configured essentially identical. The interior space is limited by the rear wall 51, two mutually opposite connection walls and the side walls 52c.

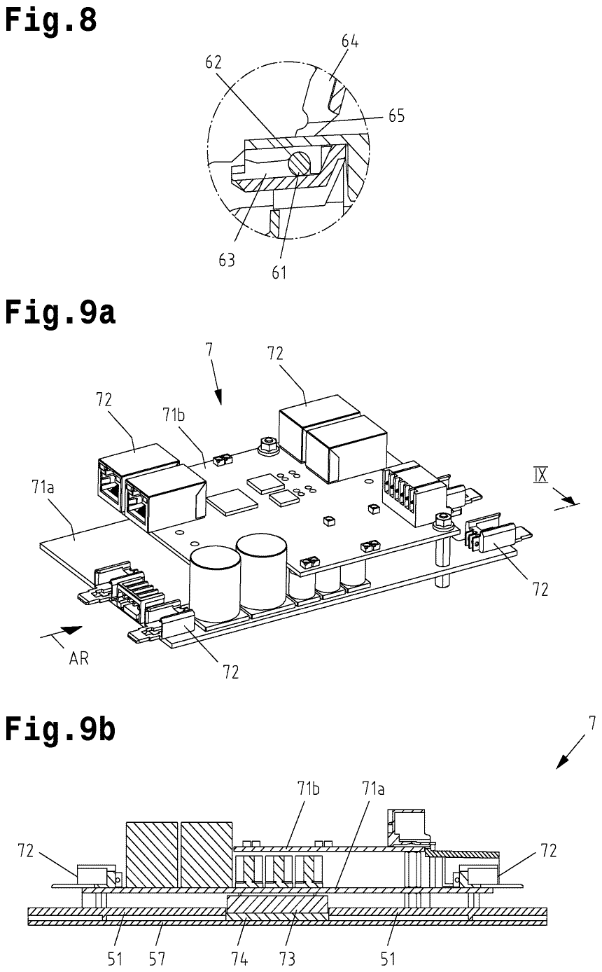

FIG. 8 shows a detailed view of the area VIII of the closing flap 6 marked with a dash-dotted line in FIG. 7b. The closing flap 6 is pivotably mounted on the housing main body 5, in particular between the housing main body 5 and the cover 58, using a hinge. To this end, the closing flap 6 has a hinge pin 61 and the housing main body 5 and/or the cover 58 has a pin receptacle 62, in which the hinge pin 61 is supported. Preferably, the pin receptacle 62 is formed by the housing main body 5 and the cover 58.

The pin receptacle 62 is configured open in a radial direction, so that the hinge pin 61 can be extracted from the pin receptacle 62 in a radial direction along an insert channel 63 extending toward the connection area AB in order to take off the closing flap 6.

Preferably, the closing flap 6 comprises a pivot arm 64, at which the hinge pin 61 is arranged. The pivot arm 64 can be configured tapered off at least in sections in order to provision a predetermined breaking point 65, at which the pivot arm 64 breaks if the closing flap 6 is moved beyond an opened position shown in FIG. 7a and FIG. 7b, for example, because a person gets caught on the opened closing flap 6 when passing, for example.

In the control electronics area SB, a control electronics unit 7 represented in FIG. 9a is arranged. FIG. 9b shows the control electronics area SB in a cross-sectional representation.

The control electronics unit 7 comprises, for example, a first printed circuit board 71a with a first control circuit and a second printed circuit board 71b with a second control circuit.

Furthermore, the control electronics unit 7 can be connected to one or multiple cables K using a connection arrangement. To this end, the connection arrangement can have multiple connection units, in particular a first connection unit arranged on the first printed circuit board 71a and a second connection unit arranged on the second printed circuit board 71b. The first connection unit and the second connection unit can each have one or multiple connections 72 for connecting a cable K.

The separating wall 52b preferably comprises multiple connection openings, through which the connections 72 are accessible and/or through which the connections 72 protrude into the connection area AB, so that a cable K can be connected to each of the connections 72, as can be seen below, in particular in FIG. 10a.

As shown in FIG. 9a, the connection arrangement can comprise connection units, in particular connections 72, arranged on opposite edges of the printed circuit boards 71a, 71b, so that, in a control device 4 with two connection areas AB, at least one connection unit is directed at each connection area AB.

Furthermore, the second printed circuit board 71b is configured preferably shorter than the first printed circuit board 71a in an extension direction, in particular in a longitudinal direction of the printed circuit boards 71a, 71b, wherein the first printed circuit board 71a and the second printed circuit board 71b are arranged above one another and centered in a longitudinal direction. The connections 72 are preferably aligned such that the connection direction AR extends parallel to the longitudinal direction of the printed circuit boards 71a, 71b. This ensures that also the connections 72 of the second connection unit are arranged offset from the connections 72 of the first connection unit in a connection direction AR.

Preferably, the longitudinal direction extends orthogonally to the opposite edges of the printed circuit boards 71a, 71b described above, on which the connections 72 are arranged.

In the connection area AB, a lettering can further be provided, which is arranged at or in the rear wall 51, for example, and designates cable routes and/or connections 72, as can be seen in FIG. 7. This facilitates an assembly, in particular a connection of the cables K. The lettering can be printed, embossed or suchlike, for example.

To achieve a low overall height, it can be provided that the first printed circuit board 71a, the second printed circuit board 71b and the rear wall 51 are arranged parallel to one another and stacked above one another in a depth direction TR.

Furthermore, the control electronics unit 7 can comprise an optional processor module 73 schematically represented in FIG. 9b, which is arranged between the first printed circuit board 71a and the rear wall 51. Preferably, the processor module 73 and the first printed circuit board 71a are arranged so as to be stacked above one another. Here, it can be expedient if the rear wall 51 has a recess adapted in shape and size to the processor module 73, in which the processor module 73 is at least partially received. Further, an optional heat conduction pad 74 can be arranged in the recess, which heat conduction pad 74 thermally connects the processor module 73 to the metal plate 57.

FIG. 10a and FIG. 10b show a perspective view of the connection area AB. The closing flap 6 is not represented here. As is readily apparent, multiple cables K are guided into the connection area AB through the lead-through openings 53 and connected to connections 72 of the control electronics unit 7. The lead-through openings 53 are preferably configured as upwardly open slots. To seal the connection area AB, it can be provided that a sealing element 54, in particular a microcellular rubber, is set into the lead-through openings 53.

Outside the connection area AB, the cables K are guided to the lead-through opening 53 through the guiding surfaces 55. The cables K are received between the guiding surfaces 55 and the frame-shaped guiding elements 56.

It can further be seen in FIG. 10a that preferably some of the cables are guided into the connection area AB through the lead-through openings 53 at a first height and some other ones of the cables are guided into the connection area AB through the lead-through openings 53 at a second height. To this end, the lead-through openings 53, in particular a lower edge of the lead-through openings 53, can be arranged at different orthogonal distances to the rear wall 51 in a depth direction TR. It can also be provided that the guiding surfaces 55 adjoin the lead-through openings 53 at different orthogonal distances to the rear wall 51. The guiding surfaces 55 form a step in a width direction of the control device 4, as can be seen in FIG. 10a. Here, a step height corresponds preferably to a distance between the first printed circuit board 71a and the second printed circuit board 71b.

As shown in FIG. 10b, preferably multiple cable fixing devices 1 described above are arranged in the connection area AB, by which cable fixing devices 1 the cables K can be fixed.

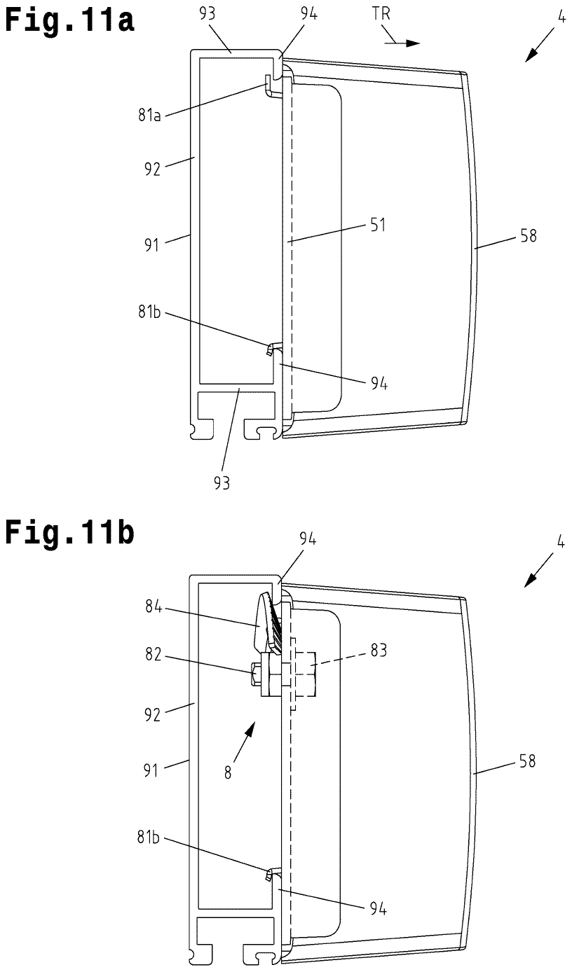

In FIG. 11a and FIG. 11b, the control device 4 is shown in a lateral view, wherein the control device 4 is mounted on a conveying device 9, in particular on a frame profile 91 of the conveying device 9.

The frame profile 91 is preferably configured C-shaped and comprises a base 92 and two limbs 93 protruding downward from the base 92. Mounting sections 94 directed toward each other and aligned parallel to the base 92 are arranged at the limbs 93.

Furthermore, a first and second hook-in strap 81a, 81b are arranged at the rear wall 51 of the control device 4. The first hook-in strap 81a faces a first longitudinal side of the rear wall 51, so that one of the mounting sections 94, in particular an upper mounting section 94, can be received between the first hook-in strap 81a and the rear wall 51. Further, the second hook-in strap 81b faces a second longitudinal side of the rear wall 51, so that the other one of the mounting sections 94, in particular a lower mounting section 94, can be received between the second hook-in strap 81b and the rear wall 51, as shown in FIG. 11a.

In a longitudinal direction of the rear wall 51, multiple first hook-in straps 81a arranged in a row and/or multiple second hook-in straps 81b arranged in a row can be provided.

The first hook-in strap 81a and the second hook-in strap 81b can thus be used to hook the control device 4 into the frame profile 91 so as to be slidable in a longitudinal direction of the frame profile 91, as represented in FIG. 11a.

To fix the control device 4 at the frame profile 91, the housing of the control device 4 comprises a fixing device 8, which has a bolt 82 passing through the rear wall 51 with a screw head 83 arranged at the inner side of the rear wall 51 and a rotary bar 84 fixedly connected to the bolt 82 and arranged at the outer side of the rear wall 51.

The rotary bar 84 is preferably arranged such that it engages behind one of the mounting sections 94, so that the mounting section 94 is fixed between the rotary bar 84 and the rear wall 51, as shown in FIG. 10. Furthermore, it can be provided that the rotary bar 84 has a corrugated surface directed toward the rear wall 51.

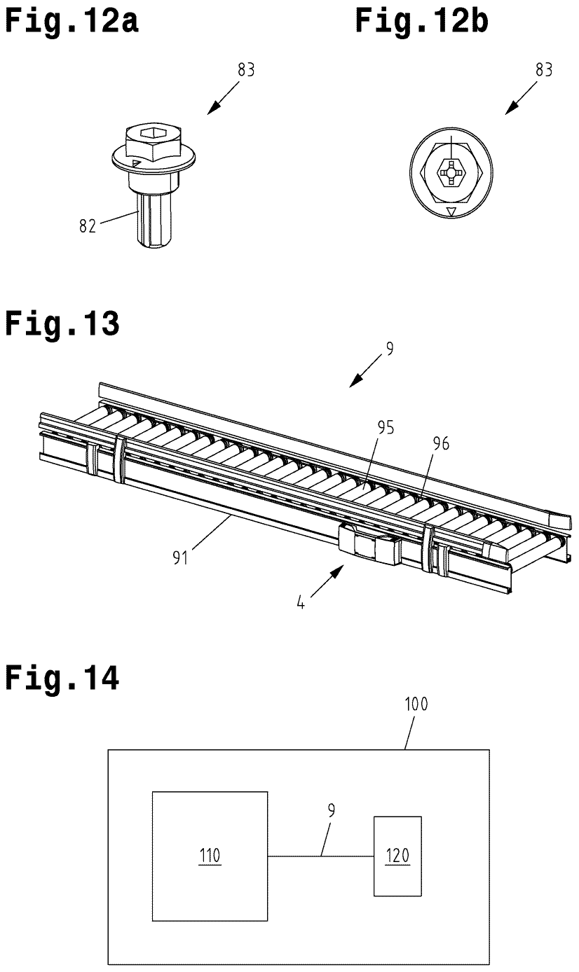

The screw head 83 is represented along with the bolt 82 in a perspective view in FIG. 12a and in a top view in FIG. 12b.

Particularly preferably, it is provided that the screw head 83 is configured as a hexagon screw, as a hexagon socket screw and/or as a cross screw. Particularly preferably, the screw head 83 is configured as combination screw head, which comprises a hexagonal contour, a hexagonal socket contour and a cross, as shown in FIG. 12a and FIG. 12b by way of example. The screw can thus be tightened with different tools.

FIG. 13 shows an exemplary conveying device 9. The conveying device 9 comprises two frame profiles 91 extending parallel to one another, between which conveying elements and/or drive elements are arranged. Preferably, the conveying device 9 is configured as a roller conveyor, as represented in FIG. 13, wherein the conveying elements are provisioned by conveyor rollers 95. It is possible that some of the conveyor rollers 95 comprise a drive element each. The drive element is an electric drive motor, for example, which is arranged inside a conveyor roller 95. Such conveyor rollers 95 form self-driven conveyor rollers 95. A self-driven conveyor roller 95 can be coupled with one or multiple other conveyor rollers 95 by one or multiple belts 96. Such (other) conveyor rollers 95 are not self-driven conveyor rollers 95.

It is also possible that the conveyor rollers 95 comprise a drive element each. These conveyor rollers 95 form self-driven conveyor rollers 95. According to this embodiment, belts 96 can be relinquished.

It is also possible that the respective drive element is arranged outside the respective conveyor roller 95 and coupled with the respective conveyor roller 95 by a transmission element, for example a belt.

Furthermore, the conveying device 9 comprises a control device 4 described above, which can be attached to one of the frame profiles 91 in the manner described above. The control device 4 is electrically connected, preferably by a cable K, to at least one drive element for controlling one or multiple drive elements.

Such a conveying device 9 can be used, for example, in a picking system 100 schematically represented in FIG. 14, wherein the conveying device 9 connects in particular an article storage 110 of the picking system 100 and a picking station 120 of the picking system 100 in terms of conveyance.

Finally, it should also be noted that the scope of protection is determined by the claims. However, the description and the drawings are to be adduced for construing the claims. Individual features or feature combinations from the different exemplary embodiments shown and described may represent independent inventive solutions.

In particular, it should also be noted the devices depicted may, in reality, also comprise more, or also fewer, components than depicted. In some cases, the shown devices and/or their components may not be depicted to scale and/or be enlarged and/or reduced in size.

Table of reference numbers

| | | | |
|---|---|---|---|
| 1 | cable fixing device | 7 | control electronics unit |
| 2 | cable clip | 71a, 71b | printed circuit board |
| 21 | main body | 72 | connection |
| 22 | press-down mechanism | 73 | processor module |
| 23 | spring arm | 74 | heat conduction pad |
| 24 | latching element | 8 | fixing device |
| 25 | catch element | 81a, 81b | hook-in strap |
| 26 | handling element | 82 | bolt |
| 27 | guiding element | 83 | screw head |
| 3 | receiving shaft | 84 | rotary bar |
| 31 | shaft wall | 9 | conveying device |
| 32 | cable support | 91 | frame profile |
| 33 | inlay element | 92 | base |
| 34 | latching element | 93 | limb |
| 37 | guiding element | 94 | mounting section |
| 4 | control device | 95 | conveyor roller |
| 5 | housing main body | 96 | belt |
| 51 | rear wall | 100 | picking system |
| 52a | connection wall | 110 | article storage |
| 52b | separating wall | 120 | picking station |
| 52c | side wall | K | cable |
| 53 | lead-through opening | AB | connection area |
| 54 | sealing element | SB | control electronics area |
| 55 | guiding surface | EE | insertion end |
| 56 | guiding element | HE | handling end |
| 57 | metal plate | α | opening angle |
| 58 | cover | d | longitudinal distance |
| 59 | screw dome | AR | connection direction |
| 6 | closing flap | ER | insertion direction |
| 61 | hinge pin | TR | depth direction |
| 62 | pin receptacle | | |
| 63 | insert channel | | |
| 64 | pivot arm | | |
| 65 | predetermined breaking | | |
| | point | | |
| 66 | side part | | |

1. A cable fixing device for fixing a cable, comprising a cable clip insertable into a receiving shaft in an insertion direction, the cable clip having a main body, a press-down mechanism arranged at the main body for fixing the cable and a spring arm, which is mounted on the main body and can be moved toward the main body opposite an action of a spring force and which has a spring-loaded first latching element, which is arranged at a side of the spring arm facing away from the main body,
characterized in that
the press-down mechanism is arranged laterally at the main body and has a first side and a second side located opposite the first side, wherein the main body and the spring arm are arranged on the second side of the press-down mechanism.

2. The cable fixing device according to claim 1, characterized in that the cable clip has a loss protection, which comprises a catch element, which cooperates with a stop element of the receiving shaft in order to limit an adjustment range of the cable clip opposite the insertion direction.

3. The cable fixing device according to claim 2, characterized in that the catch element is arranged at the main body and/or at the spring arm.

4. The cable fixing device according to claim 3, characterized in that the catch element can be moved from a securing position, in which the catch element cooperates with the stop element, to a releasing position, in which the catch element can be moved past the stop element opposite the insertion direction, by moving the spring arm.

5. The cable fixing device according to claim 1, further comprising a receiving shaft, into which the cable clip can be inserted and which has an insertion opening and a second latching element, in particular arranged at an interior wall of the receiving shaft, wherein the first latching element and the second latching element cooperate in order to limit an extraction movement opposite the insertion direction when the cable clip is in a fixing position in the receiving shaft.

6. The cable fixing device according to claim 1, characterized in that the first latching element has multiple latches, which are arranged in succession in a longitudinal direction of the spring arm.

7. The cable fixing device according to claim 1, characterized in that the press-down mechanism is configured to be resilient.

8. The cable fixing device according to claim 1, characterized in that a first guiding element is arranged at the main body, wherein the first guiding element cooperates with a second guiding element arranged at an interior wall of the receiving shaft in order to guide the main body in an insertion direction.

9. The cable fixing device according to claim 1, further comprising a cable support for receiving a cable to be fixed and an electrically conductive inlay element, which is positioned on the cable support.

10. A control device for controlling at least one drive element of a conveying device for a picking system, comprising:
a housing, which has a housing main body and an interior space, wherein the housing main body comprises a rear wall limiting the interior space, the rear wall has an inner side directed to the interior space and an outer side facing away from the interior space and the interior space comprises a connection area and a control electronics area adjoining the connection area,
a control electronics unit, which is arranged in the control electronics area,
and a connection arrangement, using which the control electronics unit can be connected to at least one cable,
characterized in that
the control device comprises a cable fixing device, which is arranged in the connection area and configured according to claim 1.

11. A control device for controlling at least one drive element of a conveying device for a picking system, comprising:
a housing, which has a housing main body and an interior space, wherein the housing main body comprises a rear wall limiting the interior space, the rear wall has an inner side directed to the interior space and an outer side facing away from the interior space and the interior space comprises a connection area and a control electronics area adjoining the connection area,
a control electronics unit, which is arranged in the control electronics area,
and a connection arrangement, using which the control electronics unit can be connected to at least one cable,
characterized in that
the housing comprises a connection wall protruding downward from the rear wall in a depth direction and limiting the connection area, wherein the connection wall has multiple lead-through openings for cables and forms multiple guiding surfaces for guiding cables at an outer side facing away from the connection area, wherein the guiding surfaces each adjoin a lead-through opening and are each configured convex, preferably sigmoid, at least in sections.

12. A control device for controlling at least one drive element of a conveying device for a picking system, comprising:
a housing, which has a housing main body and an interior space, wherein the housing main body comprises a rear wall limiting the interior space, the rear wall has an inner side directed to the interior space and an outer side facing away from the interior space and the interior space comprises a connection area and a control electronics area adjoining the connection area,
a control electronics unit, which is arranged in the control electronics area,
and a connection arrangement, using which the control electronics unit can be connected to at least one cable,
characterized in that
the control electronics unit comprises a first printed circuit board and a second printed circuit board, on each of which a control circuit is arranged and which are arranged above one another in the control electronics area of the housing, and the connection arrangement comprises a first connection unit, which can be connected to at least one first cable and is arranged on the first printed circuit board facing the connection area, and a second connection unit, which can be connected to at least one second cable and is arranged on the second printed circuit board facing the connection area, wherein the second printed circuit board is configured smaller than the first printed circuit board in at least one extension direction and arranged such in the housing that the first connection unit and the second connection unit are arranged mutually offset in a connection direction.

13. The control device according to claim 12, characterized in that the connection arrangement is arranged such that the connection direction is aligned parallel to the first printed circuit board and/or to the second printed circuit board.

14. The control device according to claim 12 or 13, characterized in that the first printed circuit board and the second printed circuit board are aligned parallel to one another and preferably parallel to the rear wall of the housing.

15. The control device according to claim 11, characterized in that the control device comprises a cable fixing device, which is arranged in the connection area.

16. The control device according to claim 12, characterized in that the housing main body has a connection wall protruding downward from the rear wall in a depth direction and limiting the connection area, wherein the connection wall has multiple lead-through openings for cables, wherein the connection wall forms multiple guiding surfaces for guiding cables at an outer side facing away from the connection area, wherein the guiding surfaces each adjoin a lead-through opening and are each configured convex.

17. The control device according to claim 11, characterized in that some of the guiding surfaces form a first group and some of the guiding surfaces form a second group, wherein the guiding surfaces of the first group adjoin the respective lead-through opening at a first orthogonal distance to the rear wall and the guiding surfaces of the second group adjoin the respective lead-through opening at a second orthogonal distance to the rear wall.

18. The control device according to claim 11, characterized in that the housing has at least one elastic sealing element, which is arranged in the lead-through openings.

19. The control device according to claim 11, characterized in that multiple guiding elements, are arranged at the outer side of the connection wall in order to guide a cable along the guiding surfaces.

20. The control device according to claim 11, characterized in that the housing has a separating wall protruding downward from the rear wall in a depth direction, which separates the connection area from the control electronics area, wherein the separating wall has multiple connection openings for the connection arrangement which connect the connection area to the control electronics area.

21. The control device according to claim 20, characterized in that the separating wall has a first separating wall section protruding downward from the rear wall in a depth direction, in which first separating wall section at least one first connection opening of the connection openings is arranged, a second separating wall section arranged offset from the first separating wall section in a connection direction and extending in a depth direction, in which second separating wall section includes at least one second connection opening of the connection openings is arranged, and a third separating wall section connecting the first separating wall section and the second separating wall section.

22. The control device according to claim 11, characterized in that the housing has a closing flap mounted on the housing main body so as to be movable between an opened position, in which the connection area is accessible, and a closed position, in which the connection area is closed.

23. The control device according to claim 22, characterized in that the closing flap is pivotably mounted on the housing main body using a hinge, wherein the hinge has a hinge pin mounted on the closing flap and a pin receptacle arranged in the housing, wherein the hinge pin can be extracted from the pin receptacle in a radial direction, so that the closing flap can be removed from the housing main body.

24. The control device according to claim 11, characterized in that the housing has a first hook-in strap arranged at the outer side of the rear wall and facing a first longitudinal side of the control device and a second hook-in strap arranged at the outer side of the rear wall and facing a second longitudinal side of the control device.

25. The control device according to claim 11, characterized in that the housing has a fixing device for attaching the control device to a frame profile of the conveying device, wherein the fixing device has a bolt passing through the rear wall with a screw head arranged at the inner side of the rear wall and a rotary bar which is fixedly connected to the bolt and arranged at the outer side of the rear wall.

26. The control device according to claim 11, characterized in that the control electronics unit comprises a processor module and the rear wall has a recess, in particular passing through the rear wall, which is adapted in shape and size to the processor module, wherein the processor module is at least partially received in the recess.

27. The control device according to claim 11, characterized in that the housing has a metal plate, which is arranged at the outer side of the rear wall.

28. The control device according to claim 26, characterized in that the control device comprises a heat conduction pad, which is arranged in the recess and which thermally connects the metal plate and the processor module.

29. A conveying device for transporting articles for a picking system, comprising frame profiles extending parallel to one another, conveying elements mounted on the frame profiles, at least one drive element for driving one or multiple conveying elements, and a control device for controlling the at least one drive element, wherein the control device is mounted on one of the frame profiles, characterized in that the control device is configured according to claim 12.

30. A picking system comprising an article storage, at least one picking station for picking articles according to orders and a conveying device for transporting articles within the picking system, characterized in that the conveying device is configured according to claim 29.

31. A use of a control device according to claim 12 for controlling at least one drive element of a conveying device.
